(19) United States
(12) Patent Application Publication
(10) Pub. No.: US 2004/0164668 A1
(43) Pub. Date: Aug. 26, 2004

(54) Color light emitting display device

(76) Inventors: Hiroshi Kanno, Osaka-city (JP); Ryuji Nishikawa, Gifu-shi (JP)

Correspondence Address: Michael A. Cantor, Esq., CANTOR COLBURN LLP, 55 Griffin Road South, Bloomfield, CT, 06002, US

(21) Appl. No.: 10/783,253

(22) Filed: Feb. 20, 2004

(30) Foreign Application Priority Data
Feb. 20, 2003 (JP) 2003-42418
Jan. 8, 2004 (JP) 2004-3082

(51) Int. Cl. H05B 33/00

(52) U.S. Cl. 313/500; 313/506; 313/505

(57) ABSTRACT

Areas of emissive regions corresponding to different color components are changed based on an emission luminance of an emissive element such as an EL element which is made of the same material and which has the same emission spectrum, efficiencies (transmission efficiency or color conversion efficiency) of color modifying elements such as color filters and color changing films, and required luminance of each of different color components necessary for obtaining white color in full-color display. This structure facilitates setting of the density of current supplied to an EL element corresponding to each emissive region to substantially the same value among the different emissive regions, which allows for realization of uniform rate of degradation of luminance, that is, lifetime in each emissive region.

### BACKGROUND OF THE INVENTION

1. Field of the Invention

The present invention relates to a color display device having a self-emissive element, such as an electroluminescence (hereinafter simply referred to as “EL”) element, and a color modifying element, such as a color filter through which only light of a certain spectrum is transmitted.

2. Description of the Related Art

Recently, EL display devices which use an EL element have attracted much attention as an alternative to cathode ray tube (CRT) display devices and liquid crystal display (LCD) devices. As a system for achieving a color EL display device, in addition to a separate provision system in which emissive materials which emit three primary colors of R, G, and B are used, a system has been proposed in which a color modifying element which emits or allows transmission of a color which is different from that of incident light, such as, for example, a color filter or a color changing film is used with an emissive material of a single color.

FIG. 1A is a planar view schematically showing an EL display device according to such a color modifying system. Pixels each having an EL element and each provided in a region surrounded by a gate signal line 51, a drain signal line 52, and a drive power supply line 53 are placed in a matrix form. A color component is assigned to each pixel and emissive regions E_{R}, E_{G}, and E_{B} realized by EL elements are formed in the pixel regions. The areas of the emissive regions E_{R}, E_{G}, and E_{B} indicate the areas of the colors which are actually viewed. The emissive regions are formed to have identical width (W) and height (H) such that the emission areas of the different color components are equal to each other.

FIG. 1B is a schematic view showing a cross section along line C-C of FIG. 1A. Color modifying elements 89 which emit light of red (R), green (G), blue (B) colors are formed on a substrate 30 and EL elements 80 which emit light of an emission color common to all EL elements 80 are formed above the color modifying element 89 at positions corresponding to the color modifying elements 89. Light from the EL element 80 is emitted to the outside through the color modifying element 89 so that a full-color display is realized using EL elements common to all pixels (having the same emission color).

A color filter, which is one type of color modifying element, is characterized in that light of a certain wavelength band within the incident light is allowed to transmit through so that a certain color component is obtained, and the color filters for R, G, and B colors have different transmission wavelength bands and transmittances, that is, the transmission (absorption) spectrum is different for each color filter. Because of this characteristic, in order to obtain different color components at a desired luminance in light which transmitted through the color filters and which is viewed from outside, density of current to be supplied to the EL element must be changed for each color component based on the transmission (absorption) spectrum of the color filter and light emission spectrum of the EL element.

A color changing film, which is another type of color modifying element, converts incident light into light of a particular wavelength band to obtain light of specific color component. More specifically, a fluorescence material or the like is used in a color changing film which absorbs incident light and emits to the outside light having a wavelength different from that of the incident light. In such a color changing film, because different materials are used for different colors of emitted light, the wavelength bands and conversion efficiencies of emitted light differ from each other. In addition, the conversion efficiencies also depend on the emission spectrum of the incident light. Therefore, in order to obtain a desired luminance in each of the color components of light emitted from the color changing film and viewed from outside, the densities of current to be supplied to the EL elements must be set for each color component based on both the conversion efficiencies of the color changing films for different color components and the emission spectrum of each EL element.

However, because EL element more rapidly degrade when the density of supplied current is increased, the degree of degradation of colors increasingly differs over time when densities of the current to be supplied to the EL elements are changed for different color components. In other words, there has been a problem in that, as the usage time of the display device is increased, brightness balance among colors, that is, white balance, is destroyed, and the lifetime of the display device as a whole is shortened.

### SUMMARY OF THE INVENTION

The present invention advantageously provides a color display device which can maintain a high display quality over a long time.

According to one aspect of the present invention, there is provided a color light emitting display device, comprising a plurality of emissive regions corresponding to a plurality of color components, wherein the plurality of emissive regions in turn comprises a plurality of emissive elements each having an emissive element layer between two electrodes and which emit light of the same color, and a plurality of color and modifying elements provided at a side of the device closer to a side to be viewed than the emissive elements corresponding to at least some of the plurality of emissive elements, for emitting light having an emission spectrum which is at least partially different from an emission spectrum of incident light; the emission light from the plurality of emissive elements is viewed, in the emissive regions corresponding to the plurality of the color modifying elements, through the corresponding color modifying elements; and areas of the plurality of emissive regions corresponding to ratios of modification efficiencies between luminance of light emitted from the color modifying element and luminance of light incident on the color modifying element among different color components of the plurality of color components, and to luminance required for each color component necessary for white display of a predetermined color represented by addition of colors.

According to another aspect of the present invention, there is provided a color light emitting display device, comprising a plurality of emissive regions corresponding to a plurality of color components, wherein the plurality of emissive regions in turn comprises a plurality of emissive elements each having an emissive element layer between two electrodes and which emit light of the same color, and a plurality of color modifying elements provided on a side of the device closer to a side to be viewed than the emissive element to correspond to at least some of the plurality of emissive elements, for emitting light having an emission spectrum which is at least partially different from an emission spectrum of incident light; light emission from the plurality of emissive elements is viewed, in the emissive regions corresponding to the plurality of color modifying elements, through the corresponding color modifying element and at least one layer which absorbs at least a portion of incident light, and the areas of the plurality of emissive regions correspond to ratios of modification efficiencies corresponding to luminance of incident light and luminance of emitting light in the color modifying element and transmission efficiencies of the layer absorbing at least a portion of the incident light, among different color components of the plurality of color components, and to a required luminance for each color component necessary for white display.

According to another aspect of the present invention, it is preferable that, in the color display device, the areas of the plurality of emissive regions are directly proportional to a ratio, regarding each color component, between luminance of light emitted through the color modifying element and the layer for absorbing at least a portion of the incident light and the luminance required for each color component necessary for white display.

According to another aspect of the present invention, it is preferable that, in the color display device, the color modifying element filters the incident light and allows transmission of light of a specific wavelength band or changes the incident light into light of a different wavelength and emits the changed light.

According to another aspect of the present invention, it is preferable that, in the color display device, the modification efficiency of the color modifying element corresponds to a transmission efficiency of the filter or to a color changing efficiency of a color changing material.

According to another aspect of the present invention, it is preferable that, in the color display device, when a power is supplied with the same current density to the emissive elements provided in the plurality of emissive regions and light is emitted, a predetermined white display or the like is achieved on a side to be viewed.

According to another aspect of the present invention, it is preferable that, in the color display device, the layer which absorbs at least a portion of the incident light includes an optical function layer. According to another aspect of the present invention, it is preferable that, in the color display device, the layer which absorbs at least a portion of the incident light includes an insulating layer which is formed between the emissive element and a side of the device in which display is viewed.

According to another aspect of the present invention, there is provided a color display device having a first emissive region and a second emissive region associated with different color components, the color display device comprising a plurality of emissive elements each having an emissive element layer between two electrodes and which emit light of the same color, and a first color modifying element and a second modifying element provided on a side of the device closer to a side to be viewed then the emissive element and corresponding to at least some of the plurality of emissive elements, for emitting light of an emission spectrum which is at least partially different from an emission spectrum of the incident light, the first and second color modifying element emitting light of different colors, wherein in the first emissive region, emission light from the emissive element is viewed through the first color modifying element; in the second emissive region, emission light from the emissive element is viewed through the second color modifying element; a modification efficiency corresponding to a ratio of light emitted from the first color modifying element with respect to light incident on the first color modifying element is higher than a modification efficiency corresponding to a ratio of light emitted from the second color modifying element with respect to light incident on the second color modifying element, and an area of the first emissive region is smaller than an area of the second emissive region.

According to another aspect of the present invention, it is preferable that, in the color display device, a ratio between the areas of the first emissive region and the second emissive region corresponds to a ratio between: a luminance, required for white color display, of the color component corresponding to the first emissive region with respect to a luminance of the light emitted from the first color modifying element; and a luminance, required for white color display, of the color component corresponding to the second emissive region with respect to a luminance of the light emitted from the second color modifying element.

Configured as described above, the present invention advantageously provides a color display device in which white and other colors, including those created by addition of colors, can be displayed while driving each of light emitting elements corresponding to different color components with the same current density, even when emissive elements having light emission of the same color are used and different color components are associated with the emissive elements and in which uniform degree of degradation (luminance halflife or the like) of a light emitting material such as an EL material of an EL element, for example, can be easily maintained.

In addition, by applying an aging treatment to ensure that the rate of degradation of light emission in a portion of wavelength bands is constant, it is possible to maintain substantially uniform current density when an arbitrary color display is performed on the overall surface even in an EL element having different rates of degradation at different wavelength bands. Thus, it is possible to supply an EL display device having a high quality and long lifetime with superior brightness balance even after the accumulated usage time becomes long.

### BRIEF DESCRIPTION OF THE DRAWINGS

FIG. 1 is a schematic view showing an arrangement of emissive regions in an EL display device of related art.

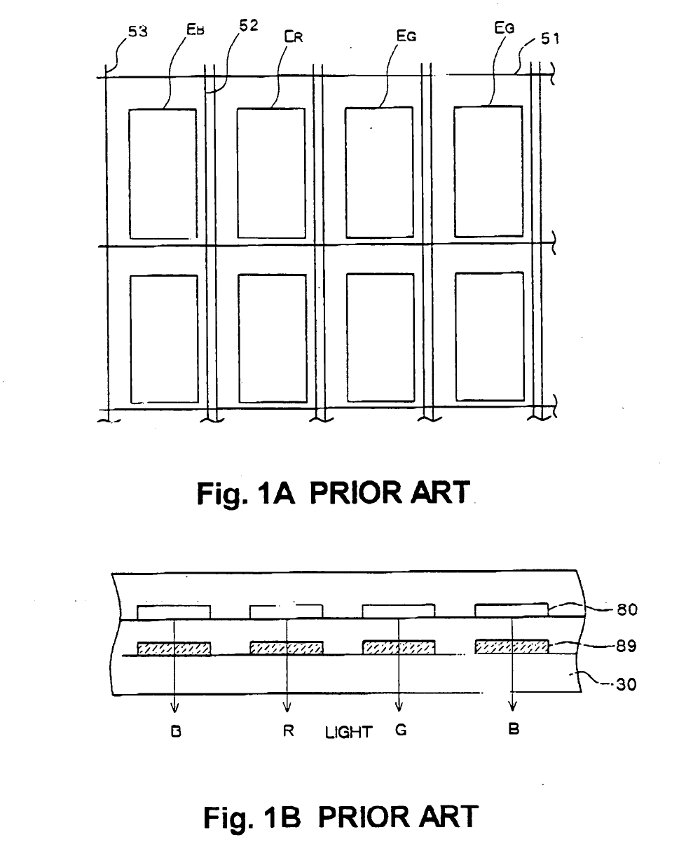

FIG. 2 is a schematic view showing an arrangement of emissive regions of an EL display device according to a preferred embodiment of the present invention.

FIG. 3 is a plan view showing emissive regions and their periphery in an EL display device according to a preferred embodiment of the present invention.

FIGS. 4A and 4B are cross sectional views of an EL display device according to a preferred embodiment of the present invention.

FIGS. 5A and 5B are cross sectional views of an EL display device according to a preferred embodiment of the present invention.

FIGS. 6A, 6B, 6C, and 6D are cross sectional views showing different manufacturing steps of an EL display device according to a preferred embodiment of the present invention.

FIG. 7 is a schematic view showing a mask used in manufacture of an EL display device according to a preferred embodiment of the present invention.

FIG. 8 is a cross sectional view of an EL display device according to a preferred embodiment of the present invention.

### DESCRIPTION OF PREFERRED EMBODIMENTS

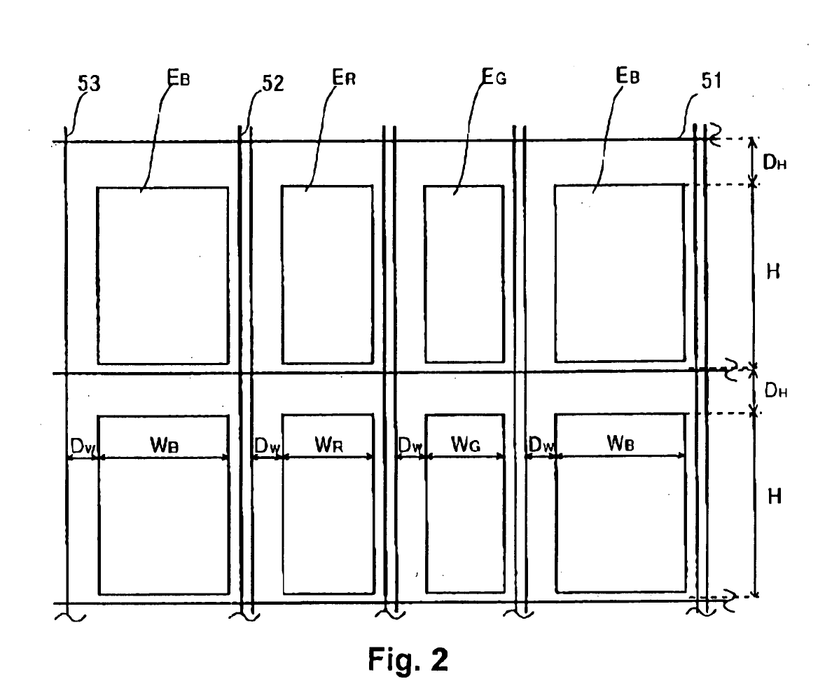

FIG. 2 is a diagram conceptually showing emissive regions of a plurality of pixels in an EL display device according to a first preferred embodiment of the present invention. In FIG. 2 is shown a configuration commonly referred to as a “stripe arrangement”, in which emissive regions of pixels associated with color components of three primary colors (R, G, and B) are periodically arranged in a row direction and the same color components are arranged in the same column. In the EL display device of the present embodiment, each of the pixels is associated with one of R, G, and B, and full-color display is achieved by synthesizing light from R, G, and B pixels. In the emissive regions of the pixels, EL elements in which the same material is used and having light emission of the same color (for example, white) are formed, as will be described below. The white light from each of the EL elements is modified (including wavelength conversion and filtering) to R, G, or B light having an emission spectrum different from each other by a color modifying element (29) such as a color filter or a color changing film provided corresponding to the EL element and is emitted to the outside. Emissive regions E_{R}, E_{G}, and E_{B} which emit light of R, G, and B colors have a common height (length in a vertical direction) H and unique widths (length in a horizontal direction) W_{R}, W_{G}, and W_{B}. A method for setting the height and widths of the emissive regions will be described further below.

Along the periphery of the plurality of emissive regions E_{R}, E_{G}, and E_{B} arranged as described, a plurality of gate signal lines 51 are formed to extend along the horizontal direction and a plurality of drain (data) signal lines 52 and a plurality of drive power supply lines 53 are formed to extend along the vertical direction. A distance D_{H} from a gate signal line 51 to each emissive region and a distance D_{W} from a drive power supply line 53 to each emissive region are set to a constant value regardless of the widths W_{R}, W_{G}, and W_{B} of the emissive regions. By setting the distances in this manner, when the gate signal line 51 and the drive power supply line 53 are placed, spaces formed on an upper side and left side of each of emissive regions E will have a common shape, which allows for placement of transistors, which are to be described later, in the same position and with the same shape. According to the present embodiment, it is possible to set the emissive regions E corresponding to each color component to a desired area and to more effectively use the space.

The above-described structure is a preferred configuration of the present invention, but the present invention is not limited to this configuration. For example, the arrangement form of the emissive regions is not limited to a stripe arrangement as described above, and may be, for example, a delta arrangement. In a delta arrangement, emissive regions corresponding to different color components are periodically arranged in the row direction and are periodically arranged in the column direction, and, in particular, the arrangement in the column direction is shifted for each row from the position of the previous row by a predetermined pitch. In a delta arrangement, three emissive regions which are adjacent to each other are emissive regions corresponding to different color components in both the row direction and column direction. The arrangement only requires that at least one of the height and the width of the emissive regions be unique for each color component and D_{H} and D_{W} need not be constant values. In consideration of the case of arrangement of the emissive regions, however, it is preferable that one of the height and width be common to the emissive regions, and, in particular, in consideration of the efficient usage of the space, it is preferable that the height be common to the emissive regions.

A method for setting emissive regions of an EL display device when a color filter which is one type of a color modifying element having a color (wavelength) conversion functionality is used will now be described. An EL element degrades more quickly as the density of current flowing through the EL element increases. The degradation in turn leads to changes in luminance (in many cases, reduction of luminance) and, thus, it is very important to achieve a uniform rate of degradation in all EL elements in order to maintain long-term brightness balance (white balance) in the display device as a whole. In consideration of this, by matching the current densities of the current to flow through the EL elements for different emissive regions, when a common material for an EL element is used in all emissive regions, it is possible to obtain uniform degrees of degradation, more specifically, uniform luminance halflives, of the EL material of the emissive regions corresponding to different color components by matching the initial luminance L0 of the color components. That is, it is possible to maintain overall brightness balance.

(1) An organic EL element to be used and color filters corresponding to different colors are selected. Because an organic EL element has a unique light emission spectrum and a color filter has a unique transmission (absorption) spectrum, it is possible to determine, from a product of these spectra, a chromaticity of light of each color component after transmitting through the color filter (emission spectrum of emitted light) and luminance before and after transmission through the color filters of different colors when current of equal current density is supplied to EL elements corresponding to the emissive regions (luminance of incident light and luminance of emitted light) and/or a ratio between the luminance of incident light and the luminance of emitted light.

When the luminance of the EL element in each emissive region before the light transmits through the color filters is respectively L_{R}, L_{G}, and L_{B} and the transmission efficiency (here, this efficiency is identical to a ratio of luminance (transmittance) of emitted light (transmitted light) with respect to the luminance of incident light) of each of the color filters is respectively TE_{R}, TE_{G}, and TE_{B}, the luminance after the light transmits through each of the color filters is, respectively, L_{R}·TE_{R}, L_{G}·TE_{G}, and L_{B}·TE_{B}. A ratio among the luminance of color components after the light transmitted through the color filters may be, for example:

L_{R}·TE_{R}:L_{G}TE_{G}:L_{B}·TE_{B}=3:8:2.

(2) From the chromaticity determined in (1), luminance of each color desired at the side of viewer for achieving white having a chromaticity necessary for display at the side of the viewer is automatically determined. For example, a ratio of the required luminance of light of each color of R, G, and B at the side of viewer may be:

a_{R}:a_{G}:a_{B}=1:2:1.

(3) From ratios in (1) and (2), luminance of the organic EL element (which is equal to the luminance of the incident light to the color filter if optical loss on the path between the element and the color filter is almost 0) before the light transmits through the color filter which is necessary for achieving the required luminance at the side of the viewer for each color can be determined. The necessary ratio of luminance among organic EL elements within emissive regions corresponding to different color components before the light transmits through the color filters in the above-described example is:

a_{R}/(L_{R}·TE_{R}):a_{G}/(L_{G}·TE_{G}):a_{B}/(L_{B}·TE_{B})=(1/3):(2/8):(1/2)=4:3:6

(4) The emission areas of the different color components are set based on the ratio of luminance calculated in (3). In the present embodiment, the emission area (S_{R}, S_{G}, and S_{B}) of different color components are set so that the areas are directly proportional to the ratio. That is, the areas are set so that the following condition (i) is satisfied.

S_{R}:S_{G}:S_{B}=a_{R}/(L_{R}·TE_{R}):a_{G}/(L_{G}·TE_{G}):a_{B}/(L_{B}·TE_{B}) (i)

In the above example, the condition (i) becomes:

S_{R}:S_{G}:S_{B}=(1/3):(2/8):(1/2)=4:3:6

Therefore, the areas of R, G, and B can be set to satisfy this ratio. In this procedure, it is preferable to set the widths W_{R}, W_{G}, and W_{B} of the emissive regions corresponding to the different color components to be directly proportional to the ratio calculated in the above-described procedure (3) based on the ratio of luminance. By setting the areas in this manner, the heights of the emissive regions H_{R}, H_{G}, and H_{B} can be set equal to each other, which allows for easy design and efficient usage of the space.

In order to prevent reduction of contrast by a reflection of light incident from the outside of the display device, a reflection prevention film and/or a polarization film may be provided on a side closer to the viewer than an organic EL element. In addition, in order to prevent damage to the EL element due exposure to ultraviolet light (UV rays) from the outside, an optical function layer such as an UV cut film may be used on the side closer to the viewer than an organic EL element. Each of these optical function layers such as the reflection prevention film, polarization film, and UV cut film has a unique transmission (absorption) spectrum, and thus at least a portion of the light incident on these layers is absorbed. Therefore, when these optical function layers are to be used, in addition to the transmission (absorption) spectra of the color filters, the transmission efficiencies (transmission (absorption) spectra or optical losses) of these layers must also be considered in order to set the emission areas. In this case, the change in luminance (ratio of luminance) in the above-described process (1) may be set to, instead of a ratio of emitted light with respect to incident light in the color filter, a change in luminance (ratio in luminance) before and after transmission of light through all of the color filter, reflection prevention film, polarization film, and/or UV cut film. In addition, when other films or layers are also formed on the side closer to the viewer than the EL element, for example, when a buffer layer, a gate insulating layer of a TFT, an interlayer insulating layer, and a planarization layer which will be described below are formed between the EL element and the substrate, it is preferable that the transmission efficiencies (transmission (absorption) spectra) of these layers are also considered. More specifically, in place of the “L·TE” term in the above-described equations, a product of the luminance of the incident light, a modification efficiency of the color modifying element such as a color filter, and a transmission efficiency of the optical function layer may be used.

In an EL display device having a color modifying element such as a color filter and a color changing film, organic EL elements having a common structure are formed over the entire surface. In other words, because organic layers which are common (that is, made of the same material) over the entire surface can be formed, by supplying current of equal current density to the EL elements in different emissive regions, it is possible to obtain a uniform rate of degradation of emission luminance in all emissive regions. However, depending on the layer structure of the emissive layer and emissive material used in the emissive layer, etc., different emission bands may have different degradation rates, and therefore, the luminance halflives may differ. For example, in a structure in which an emissive layer comprising a plurality of different layers which emit light having colors which complement each other is employed to realize white color by addition of light from the different layers, the luminance halflives of the different layers differ from each other, and, in a structure in which the emissive layer is made of a single emissive material, but the light emission spectrum changes as the emission time elapses. In cases such as these, it is possible to obtain a uniform luminance halflives in all emissive regions by additionally considering the luminance halflives in various wavelengths bands in the process of determining the emission area. That is, if the luminance halflives of emission luminance in wavelength bands corresponding to R, G, and B are respectively T_{R}, T_{G}, and T_{B}, the required condition is represented by the following equation (ii).

S_{R}:S_{G}:S_{B}=a_{R}/(L_{R}·TE_{R}·T_{R}):a_{G}/(L_{G}·TE_{G}·T_{G}): a_{B}/(L_{B}·TE_{B}·T_{B}) (ii)

In addition, there may be a situation in which a change in the rate of degradation (luminance change) of emission in the overall emissive layer or in an arbitrary wavelength band is high at initial stages of emission and the rate of degradation converges to a constant value after a predetermined period is elapsed. In such cases, the emission area must be determined in consideration of the change with respect to time in the rate of degradation at the initial stages of emission. However, in order to eliminate this need for considering the change in luminance with respect to time at the initial stages (because the amount of change may be large in some cases), it is also possible to apply an aging treatment to the display device (or display panel) before the device or panel is shipped from a factory. In this case, by using, as the values for T (T_{R}, T_{G}, and T_{B}), a luminance halflife measured or simulated after the aging treatment is applied, the luminance halflives can be more precisely matched. More specifically, for example, when the rate of degradation changes uniformly for all wavelength bands, or when only the rate of degradation of an arbitrary wavelength band changes, it is desirable that an aging treatment be applied until the rate of degradation becomes stable. When changes in rates of degradation with respect to time differ in different wavelength bands, on the other hand, it is desirable that the aging treatment be applied until the rate of degradation becomes constant in at least one wavelength band. However, as the aging treatment and the luminance halflives are in a “tradeoff” relationship, when uniform luminance halflife is of higher priority, it is desirable to apply the aging treatment until the rates of degradation become constant for all wavelength bands and, when length of the luminance halflife is of higher priority, it is desirable to apply the aging treatment until the rate of degradation becomes constant in one wavelength band.

With the above-described method, it is possible to set the emissive region for each color component for realizing a desired white display (and consequently, full-color display) while maintaining a constant value for the density of the current to be applied to the organic EL elements having the same structure. Thus, when all of the organic EL elements are driven for the same amount of time and with the same current density, the organic EL elements will reach the luminance halflife timing almost simultaneously. Depending on the design, there may be cases in which the emission areas cannot be secured to correspond to the ratio of required luminance for the EL elements in emissive regions corresponding to different color components. In such a case, it is possible to change (increase or decrease) the current density of the current to be supplied to the EL element in which the emission area cannot be secured with respect to EL elements corresponding to other color components within a range which does not affect the function of the overall device as a display device, to secure the required luminance, even if such a change results in different luminance halflives. In the present embodiment, the luminance halflives are assumed to be substantially equal within the range which does not affect the function of the overall device as a display device.

When a color changing film in which, for example, a fluorescent material is used and incident light is converted to light in a certain wavelength band to obtain light of a specific color component is used as the color modifying element instead of the color filter, it is possible to achieve the luminance required for color display while maintaining the same current density for currents to be applied to the organic EL elements of the emissive regions of different color components through the same method of (1)-(4) described above by replacing the transmission efficiency of the color filter by a conversion efficiency of the color changing film.

In addition, when a combined structure of a color changing film and a color filter is used as the color modifying element, only the transmission efficiency (transmission (absorption) spectrum) of the color filter need be considered in addition to the conversion efficiency of the color changing film, and it is possible to obtain the emission areas by using a ratio of luminance before and after light transmits through the color changing film and the color filter in place of the luminance ratio (luminance of emitted light/luminance of incident light) in step (1).

When a color changing film is used in conjunction with a reflection prevention film and/or polarization film, it is only necessary that the conversion efficiency of the color changing film and the transmission efficiency (transmission (absorption) spectrum) of the reflection prevention film and/or the polarization films be considered, and it is possible to obtain the emission areas by using a ratio of luminance before and after light transmits through the color changing film and the reflection prevention film and/or the polarization film in place of the luminance ratio in step (1).

In addition, when either a color filter or a color changing film is used, when the desired color component at the side of the viewer among a plurality of emissive regions and the emission color of the organic EL element match, it is possible to eliminate a color modifying element in the corresponding emissive region and allow the light emission from the EL element to be emitted unchanged. In such a case, regarding the color component of the original light, the emission area can be calculated through the above-described process with the ratio of change of luminance (efficiency; TE) in step (1) being 1. When the luminance halflives are to be additionally considered in setting the emissive regions, instead of considering the rate of degradation and luminance halflives of emissive layers in wavelength bands corresponding to the color components of the pixels as in the color filter system, it is possible to consider the rate of degradation and luminance halflives of the wavelength band used for conversion by the color changing film among the emission light of the EL element.

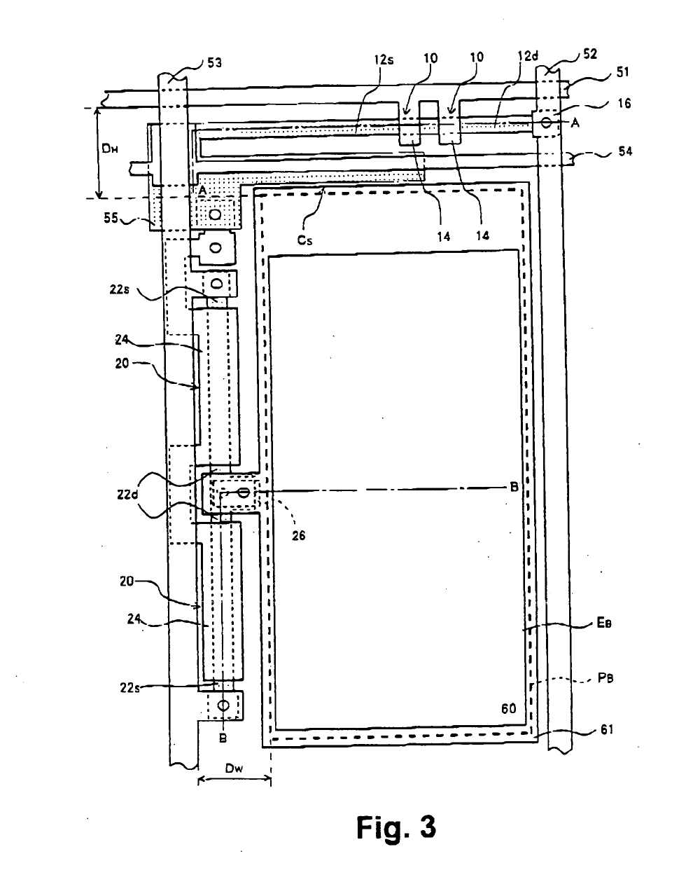

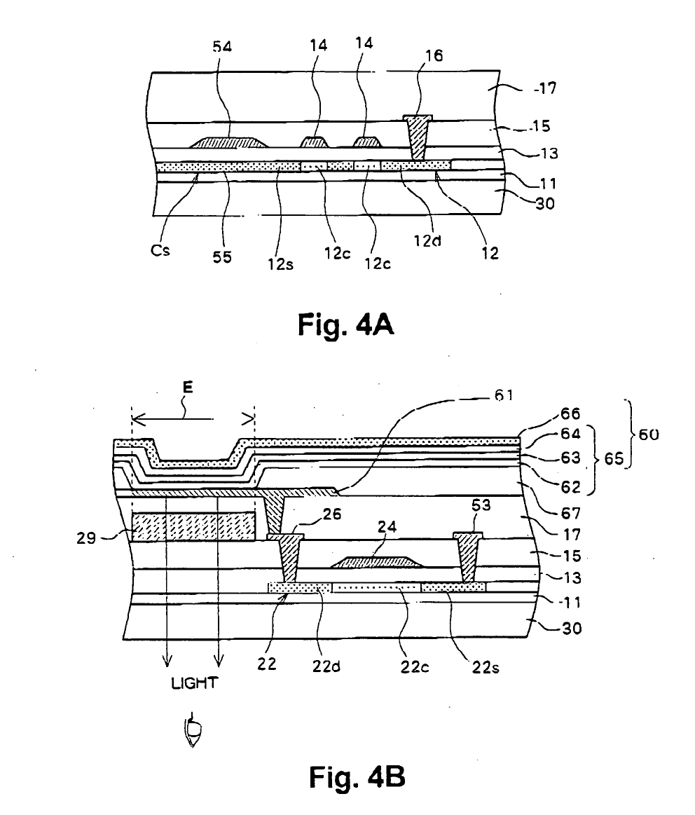

FIG. 3 is a plan view showing the periphery of the emissive region E_{R} of FIG. 2. FIGS. 4A and 4B are cross sectional views along the cross sections A-A and B-B of FIG. 3. A structure around an emissive region of an EL display device according to a preferred embodiment of the present invention will now be described referring to these diagrams.

Two first TFTs 10 connected in series with respect to a drain signal line 52 and a portion of a storage capacitor electrode line 54 and a storage capacitor electrode 55 are placed between an emissive region E_{B} and a gate electrode 51. Each gate 14 of two TFTs 10 is connected to the gate signal line 51 (in the illustrated example, the gate 14 and the gate signal line 51 are integral). A drain 12d of the TFT 10 which is placed on the side of the drain signal line 52 is connected to a drain signal line 52. A source 12s of the TFT 10 which is not directly connected to the drain signal line 52 is electrically connected to the storage capacitor electrode 55 which forms a storage capacitor C_{S} with the storage capacitor electrode line 54 (in the illustrated example, the source 12s of this TFT 10 is integrally formed with the storage capacitor electrode 55 using the same semiconductor layer). The source 12s of this TFT 10 is connected to gates 24 of two second TFTs 20, and the second TFTs 20 are connected in parallel between a drive power supply line 53 and an organic EL element 60. Specifically, sources 22s of the two TFTs 20 are connected to the drive power supply line 53 and drains 22d of the two TFTs 20 are connected to a drain electrode 26 and via the drain electrode 26 to an electrode 61 of the organic EL element 60 to be described below. An emissive element layer 65 and an electrode 66 are layered above the electrode 61 of the organic El element 60.

The storage capacitor electrode line 54 is formed to oppose a conductive layer (semiconductor layer) 12 which also functions as the storage capacitor electrode 55 connected the source 12s of the TFT 10, with a gate insulating film 13 therebetween. With such a structure, charges are accumulated between the storage capacitor electrode line 54 and the storage capacitor electrode 55 to form a capacitor. The capacitor becomes a storage capacitor C_{S} for storing a voltage to be applied to the gate electrode 24 of the second TFT 20.

Although the emissive region E_{B} having a rectangular shape is shown in FIG. 3, in reality, the shape of the emissive region E_{B} may not be rectangular in order to secure as much emission area as possible or due to design constraints. In the present embodiment, the shape of the emissive region need not be strictly rectangular and may be a shape which is approximately rectangular, and the present embodiment will be described referring to these approximate rectangular shapes also as rectangular. In the above-described drawings, an emissive region E_{B} corresponding to blue (B) and peripheral structure thereof have been described. The structure is not limited to B and similar structures are formed for emissive regions E_{G} and E_{R} corresponding respectively to green (G) and red (R).

Next, a structure of the first TFT 10 for switching and the storage capacitor C_{S} which is connected to the source of the first TFT 10 will be described. In this structure, a top gate type TFT is employed as the first TFT 10 in which a gate 14 is placed above an active layer 12. An insulating film (buffer film) 11 made of, for example, SiN and SiO₂ is layered on a substrate 30. Above the insulating film 11, an active layer 12 made of a polycrystalline silicon (hereinafter referred to as “p-Si”) film is formed in which a drain 12d, a source 12s, and a channel 12c located between the drain 12d and the source 12s are formed. The source 12s is integrally formed with the storage capacitor electrode 55 which is also made of p-Si and is electrically connected to the storage capacitor electrode 55 (the source 12s and the electrode 55 need not be integrally formed, but the source 12s and the electrode 55 must be electrically connected). A gate insulating film 13 made of SiO₂ and SiN is layered covering the active layer 12 and the storage capacitor electrode 55. Above the gate insulating film 13, a gate electrode 14 and the storage capacitor electrode line 54 made of a high-melting point metal such as chromium (Cr) and molybdenum (MO) are formed. The gate electrode 14 is provided above the channel 12c and the first TFT 10 is formed in this region. The storage capacitor electrode line 54 is provided to oppose the storage capacitor electrode 55 so that the storage capacitor C_{S} is formed in this opposing region.

An interlayer insulating film 15 made of SiO₂ film, SiN film, or the like is formed over the entire surface covering the gate electrode 14 and the gate insulating film 13. A drain electrode 16 made of a metal such as Al is formed through a contact hole formed in the interlayer insulating film 15 and the gate insulating film 13 at a position corresponding to the drain 12d, and a planarization film 17 which is made of an organic resin or the like is formed over the entire surface for planarizing the surface.

A structure of the second TFT 20 for driving the organic EL element and the organic EL element 60 which is layered above the second TFT 20 will now be described. In this structure, the second TFT 20 is also formed as a top gate type TFT similar to the first TFT 10, and the layers and films which are common with those of the first TFT 10 are formed simultaneously with the layers and films of the first TFT 10. Some of these structures are assigned the same reference numerals, as can be seen by comparing FIG. 4A and FIG. 4B. An insulating film 11 which is made of, for example, SiN and SiO₂ is layered on a substrate 30. Above the insulating film 11, an active layer 22 made of a p-Si film similar to the active layer of the first TFT 10 is formed. In the active layer 22, a drain 22d, a source 22s, and a channel 22c located between the drain 22d and the source 22s are formed. A gate insulating film 13 made of SiO₂ and SiN is layered covering the active layer 22. A gate electrode 24 made of a high melting point metal such as Cr and Mo is formed over the channel 22c. The second TFT 20 is formed with such a structure. Depending on the structure of the TFTs provided in each pixel, that is, the structure of the circuit or the like in each pixel, the first TFT 10 and the second TFT 20 may be of the same conductivity type or of different conductivity types, but the active layers 12 and 22 of these TFTs may be formed simultaneously, with an exception that the impurity to be doped into the p-Si film may be different. More specifically, the active layers may be formed by, for example, forming an a-Si film and polycrystallizing the a-Si film through laser annealing or the like. As the gate electrode 24 of the second TFT 20 also, a layer which is formed and patterned simultaneously with the gat electrode 14 of the first TFT 10 may be used.

An interlayer insulating film 15 made of an SiO₂ film, SiN film, or the like is formed over the entire surface above the gate electrode 24 and the gate insulating film 13. A drain electrode 26 made of a metal and a drive power supply line 53 connected to a drive power supply are placed through contact holes formed in the interlayer insulating film 15 and the gate insulating film 13 at positions corresponding to the source 22s and the drain 22d. In addition, a color modifying element 29 comprising a color filter or a color changing film for extracting light of a specific wavelength band from light emission from the organic EL element 60 is placed over a predetermined position of the interlayer insulating film 15. A planarization film 17 for planarizing the surface is layered to cover these structures. An electrode 61 made of an ITO (Indium Tin Oxide) which is connected to the drain electrode 26 through a contact hole formed through the planarization film 17 is formed over the planarization film 17. An emissive element layer 65 which has, for example, a three-layered structure of a hole transport layer 62, an emissive layer 63, and an electron transport layer 64 is layered and formed above the electrode 61 and an electrode 66 made of an aluminum alloy or the like is formed covering the emissive element layer 65. The emissive element layer 65 is not limited to the illustrated three-layered structure, and may be of a single layer structure or a layered structure of 2, 4, or more layers, depending on the organic material to be used, etc. In the example structure of FIG. 4B, in a partial region between a hole transport layer 62 which is the lowermost layer in the emissive element layer 65 and the electrode 61, a second planarization film 67 made of an insulating resin is layered and formed. When the lowermost layer of the emissive element layer 65 is, for example, a hole injection layer, the second planarization film 67 is formed between the hole injection layer and the electrode 61. An opening is formed in the second planarization film 67 above the electrode 61 so that a region in which the surface of the electrode 61 is exposed and is directly in contact with the emissive element layer 65 is limited. In other words, the emissive region E is defined by the opening in the second planarization film 67.

It is preferable that the color modifying element 29 be formed as close to the surface of emission (in the illustrated structure, on the side of the substrate 30) from the viewpoint of reduction in parallax or the like. As shown in FIG. 4B, it is desirable that the color modifying element 29 is formed, for example, on the interlayer insulating film 15 from the viewpoint of parallax and problems during the manufacturing process. However, the color modifying element 29 may be formed on any surface including the surface of the substrate 30 on the side of the viewer, as long as the color modifying element 29 is formed at the side closer to the viewer than the electrode 61 (and organic EL element 60). When the reflection prevention film and the polarization film described above are to be formed, these films may be provided on, for example, the surface of the substrate 30 on the side of the viewer.

When a material which emits light of one of R, G, and B required for full-color display is used as the emissive material (EL material) of the organic EL element 60 instead of, for example, white, there is no need to place the color modifying element 29 in the emissive region of the corresponding one of the color components of R, G, and B. For example, when a blue emissive material is used as a material of the emissive layer 63, no color modifying element is required in the emissive regions corresponding to blue. When a color changing film is used as the color modifying element 29, for example, it is not necessary to form the color changing films corresponding to all color components. However, even in these cases, when a color purity of the emission color of the organic EL element 60 is low, it is possible to use, as the color modifying element 29, for example, a color filter having a low transmittance for wavelengths of other components or a color changing film for converting wavelength (converting color) of blue incident light to blue light having a higher purity.

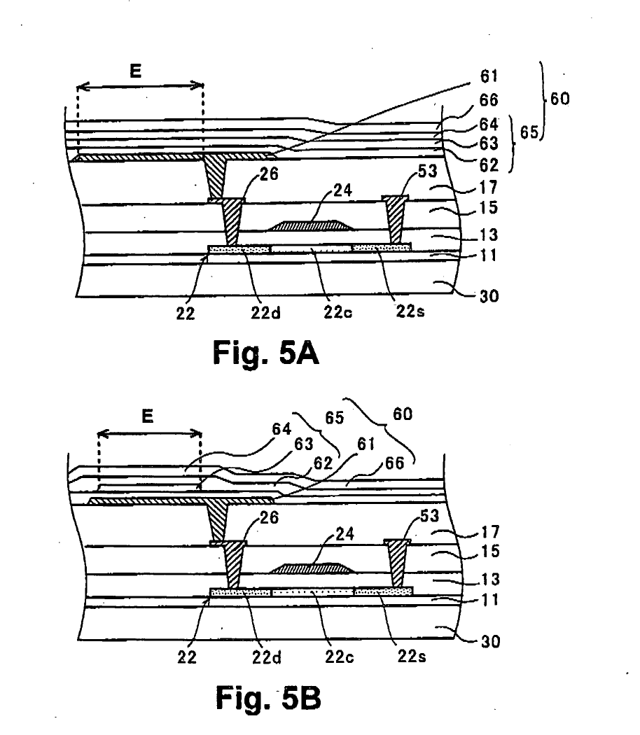

As a method for manufacturing an emissive region E into a shape set as in the preferred embodiment of the present invention, in addition to the above-described first method which uses the second planarization film 67, there is a second method in which the second planarization film 67 is not used, but the shape of the emissive area is adjusted by a shape of the electrode 61 of the organic EL element, as shown in FIG. 5A. The emissive region E in such a configuration is defined by the electrode 61. In addition, there also is a third method in which the second planarization film 67 is not used similar to the second method, but the emissive region E is adjusted by the emissive layer 63, as shown in FIG. 5B. The emissive region E in such a configuration is defined by the pattern of the emissive layer 63.

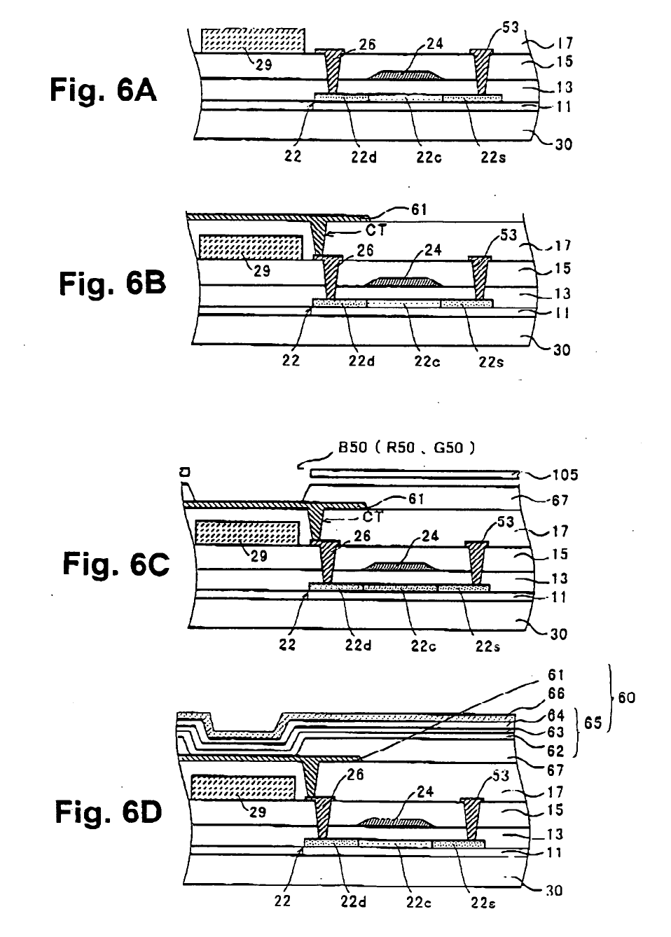

FIGS. 6A 6D are cross sectional views showing different manufacturing steps in a method for manufacturing an EL display device according to the present embodiment. These figures correspond to the cross sectional view along the B-B cross section shown in FIG. 3. Manufacturing steps of an EL display device using the first method will now be described referring to these drawings.

FIG. 6A is a cross sectional view showing a first step. In this step, after a second TFT 20 is formed and an interlayer insulating film 15 is formed covering the TFT 20 through a known method, a driver power supply line 53 which is connected to the source 22s of the TFT 20 through a contact hole formed in a corresponding position and a drain electrode 26 which is connected to the drain 22d of the TFT 20 through a contact hole formed in a corresponding position are formed. Then, a color modifying element 29 is formed on a region over the interlayer insulating film 15 at positions corresponding to emissive regions using a color filter, color changing film, etc. When a color filter is used as the color modifying element 29, a transferring method or spin coating is used to form the color filter. The transferring method will now be described. A material of a color filter of one of the colors is transferred to the entire surface of the substrate using a transfer film and the color filter material transferred to regions in which the color filter material is not necessary is removed through etching, to thereby form a first color filter. Next, a material of a color filter of a color other than that of the first color filter is transferred in a similar manner, and unnecessary portions are etched away to form a second color filter. In this process, some means must be provided for ensuring that the first color filter which is formed previously is not damaged. A third color filter is then formed by transferring a material of a color filter of a color different from those of two previous colors in similar manner. As above, some means must be provided for ensuring that the first and second color filters are not damaged. When a color modifying element 29 is to be formed using a color changing film, a patterning process is applied through wet etching.

FIG. 6B is a cross sectional view showing a second step in the method now being described. In this step, a first planarization film 17 made of a resin or the like is layered through spin coating or the like on the interlayer insulating film 15 covering the color modifying element 29, drive power supply line 53, and drain electrode 26. Then, a contact hole CT is formed through the planarization film 17, which reaches the drain electrode 26.

A layer 28 made of a transparent material such as, for example, ITO is then layered through sputtering to entirely cover the contact hole CT and the planarization film 17. A resist is then applied on the ITO layer 28 and is patterned by exposing and developing using a mask. Using the patterned resist as a mask, the ITO layer 28 is etched so that the electrode 61 made of ITO is formed, which is connected to the drain electrode 26 through the contact hole CT.

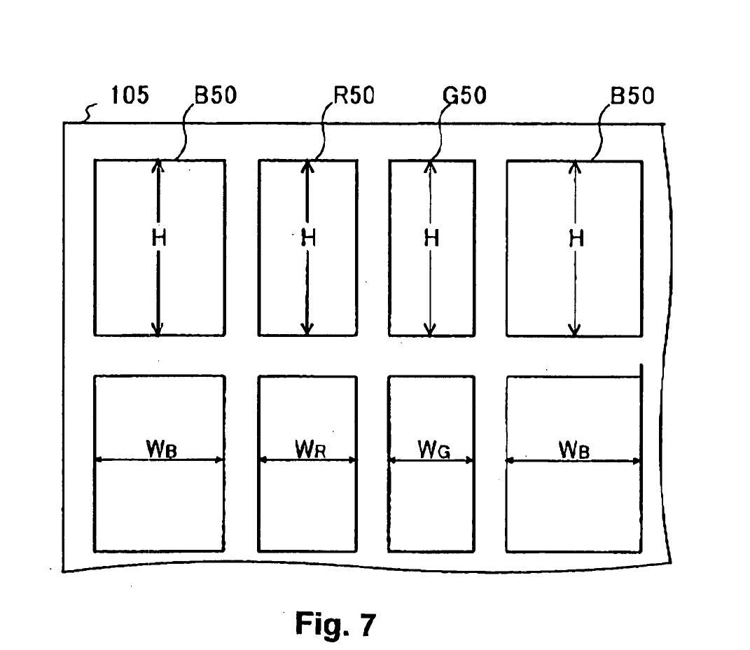

FIG. 6C is a cross sectional view showing a third step. In the third step, a material of a second planarization film made of an organic resin or the like is layered on the electrode 61 and the planarization film 17 through spin coating or the like. Then, the second planarization film material is exposed using a mask 105 and developed to form a second planarization film 67. In the example mask 105 used to illustrate this process, a plurality of openings R50, G50, and B50 are formed, as shown in FIG. 7. The openings R50, G50, and B50 of the mask have widths W_{R}, W_{G}, and W_{B} and a height H which are identical to those of the corresponding emissive regions (E_{R}, E_{G}, and E_{B}). By patterning the second planarization material layer using the mask 105 through photolithography, openings are formed in the second planarization film 67 in positions and shapes corresponding to the emissive regions E and the surface of the electrode 61 is exposed in the opening.

FIG. 6D is a cross sectional view showing a fourth step. In the fourth step, an emissive element layer 65 made of a hole transport layer 62, an emissive layer 63, and an electron transport layer 64 is evaporated over the entire surface of the substrate above the electrode 61 and the planarization film 67, covering the exposed electrode 61. Then, an electrode 66 is evaporated over the emissive element layer 65. Because resistances of these emissive materials are relatively high, only the emissive element layer 65 in a region between the electrode 61 and the electrode 66 becomes the emissive region.

The second manufacturing method in which the emissive region E is adjusted by the electrode 61 will now be described. In this method, the device may be formed in steps similar to the above-described first method, except that the second planarization film 67 is not formed. Specifically, the electrode 61 is formed in the same shape and position as the emissive region using a mask, and then, the emissive element layer 65 and the electrode 66 are formed covering the electrode 61. In this manner, an EL display device having a cross sectional structure of FIG. 5A can be obtained. As the mask for forming the electrode 61, a mask having openings in positions and shapes corresponding to the emissive regions E may be used similar to the mask described above regarding FIG. 7.

According to the preferred embodiment described above, by setting the emissive regions so that a desired luminance is achieved in each color component and the degradations of the EL material within all emissive regions are matched, it is possible to obtain an EL display device of high quality in which the brightness balance among color components (white balance) is not destroyed regardless of the usage time of the display device.

In the above-described example of the preferred embodiment, a bottom emission type EL display device has been described. However, the present invention is not limited to such a configuration and may be applied to a top emission type EL display device in which the emission from an EL element is output from a side opposite to that of the TFT substrate. In a top emission type device, because the organic EL element is placed on a side closer to the viewer than non-transparent materials such as the TFT and various signal lines, that is, materials that block light emission, degree of freedom for design is higher and the emissive area can be widened. In other words, there is no limitation that, substantially, the emissive region can be formed only in a region surrounded by the TFT, various signal lines, and drive power supply line in which no non-transparent material is placed closer to the viewer side than the organic EL element 60, as shown in FIGS. 2 and 3. Therefore, the top gate type device allows for an advantage, in addition to the possibility of forming the emissive region to cover the entire region surrounded by various signal lines and the drive power supply line 53, that the emissive region E can be formed exceeding the various single lines and drive power supply line 53 in any layout which allows for a contact between the drain electrode 26 of the corresponding TFT 20 and the electrode 61. Similarly as in bottom emission type structure, in a top emission type device, in consideration of the ease of the arrangement of the emissive regions, it is desirable to set one of the height and width of the emissive regions to be common to all emissive regions, and it is particularly desirable to set the height of the emissive regions to be common.

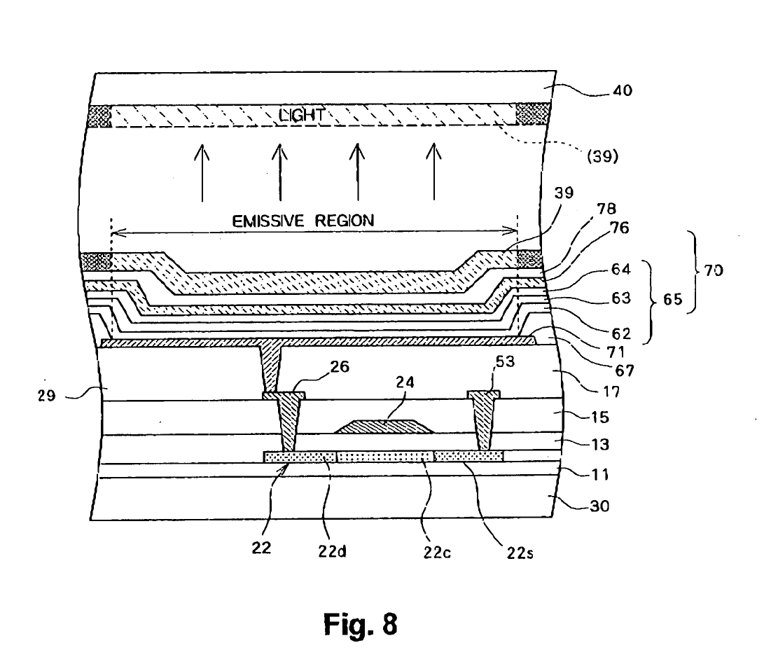

AN example of a top emission type EL display device will now be described. FIG. 8 is a diagram showing a cross sectional structure of relevant portions of a top emission type EL display device. Layers identical to those shown in FIG. 4B are assigned the same reference numerals. The TFT 20, drain electrode 26, and drive power supply line 53 are identical to those shown in FIG. 4B. A planarization film 17 is layered covering the drain electrode 26, drive power supply line 53, and interlayer insulating film 15 for planarizing the surface. An electrode 71 made of a conductor such as, for example, ITO or a metal is formed over the planarization film 17 covering a contact hole formed through the planarization film 17. The electrode 17 is electrically connected to the drain electrode 26 through the contact hole. In FIG. 8, the electrode 71 is formed covering the TFT 20, but when it is desired to further increase the area of the emissive region, it is possible to form the electrode 71 covering the TFT 10 which is used as a switching element and a storage capacitor electrode 55 (not shown), etc. Then, an emissive element layer 65 is layered and formed over the electrode 71 and an electrode 76 made of a transparent conductive material is formed covering the emissive element layer 65. A transparent protection film 78 made of an acrylic resin is layered over the electrode 76 to cover an organic EL element 70 formed of the electrode 71, emissive element layer 65, and electrode 76. A color modifying element 39 is formed over the transparent protection film 78. Similar to FIG. 4B, the emissive region E is defined by a region in which the electrode 71 is exposed due to an opening of the second planarization film 67. However, similar to other EL display devices of bottom emission type, it is also possible to define the emissive regions E, for example, through methods shown in FIGS. 5A and 5B.

A top emission type EL display device to which the present invention is applicable is not limited to the above-described structures. For example, it is possible to employ a structure in which the transparent protection film 78 is not layered on the organic EL element 70 and a sealing substrate (opposing substrate) 10 is adhered at a periphery of the substrate 30 on the side on which the organic EL element 70 is formed to seal the element 70. In this case, the color modifying element 39 may be formed on one of the major surfaces of the sealing substrate 40, for example, on the side facing the elements as shown in FIG. 8 by dotted lines, or the color modifying element 39 may alternatively be formed on the electrode 76 (cathode) similar to the structure in which the sealing is achieved by the protection film 78. Alternatively, both the transparent protection film 78 and the sealing substrate (opposing substrate) 40 may be provided and the color modifying element 39 may be formed on either one of the transparent protection film 78 and the sealing substrate 40 or between the cathode 76 and the transparent protection film 78.

The present invention is not limited to the above-described embodiment. For example, as described earlier, the emissive regions may be arranged in a delta arrangement instead of a stripe arrangement as described in the above examples. When a delta arrangement is employed, various configurations may be used such as, for example, configurations with an amount of shift in the column direction for each row of emissive region being 0.5 region, 1 region, 1.5 regions, 2 regions, etc. The shape of the emissive region is not limited to rectangular and may alternatively be L-shaped, a polygon, or other shapes, and any shape which is reasonable for designing a display device may be employed. The manufacturing method and materials for TFTs may be any of known method or material, or a new material may be used. In addition, although in the above description a top gate type TFT has been explained, a bottom gate type TFT may in which the gate electrode is provided on a side closer to the substrate than the active layer may alternatively be used.

What is claimed is:

1. A color light emitting display device, comprising:
a plurality of emissive regions corresponding to a plurality of color components, wherein
the plurality of emissive regions comprises:
a plurality of emissive elements each having an emissive element layer between two electrodes and which emit light of the same color, and
a plurality of color modifying elements provided at a side of the device closer to a side to be viewed than the emissive elements corresponding to at least some of the plurality of emissive elements, for emitting light having an emission spectrum which is at least partially different from an emission spectrum of incident light;
the emission light from the plurality of emissive elements is viewed, in the emissive regions corresponding to the plurality of the color modifying elements, through the corresponding color modifying elements; and
areas of the plurality of emissive regions correspond to ratios of modification efficiencies between luminance of light emitted from the color modifying element and luminance of light incident on the color modifying element among different color components of the plurality of color components, and to luminance required for each color component necessary for white display.

2. A color display device according to claim 1, wherein the areas of the plurality of emissive regions are directly proportional to ratios among the color components between required luminance of the color components necessary for the white display and the luminance of light emitted from the color modifying element.

3. A color display device according to claim 1, wherein the color modifying element filters the incident light and allows transmission of light of a specific wavelength band.

4. A color display device according to claim 3, wherein the modification efficiency of the color modifying element corresponds to a transmission efficiency of the color modifying element.

5. A color display device according to claim 1, wherein the color modifying element changes the incident light into light of a different wavelength and emits the changed light.

6. A color display device according to claim 5, wherein the modification efficiency of the color modifying element corresponds to a color changing efficiency of a color changing material.

7. A color display device according to claim 1, wherein the color modifying element changes the incident light into light of a different wavelength, filters the changed light, and allows transmission of light of a specific wavelength band.

8. A color display device according to claim 1, wherein when a power is supplied with the same current density to the emissive elements provided in the plurality of emissive regions and light is emitted, a predetermined white display is achieved on a side to be viewed.

9. A color display device according to claim 1, wherein the color modifying element is provided between the emissive element and the side of the display to be closer to the side to be viewed, in emissive regions having a required color component for the corresponding emissive regions which is different from the color component of emission color of the emissive element.

10. A color light emitting display device, comprising:
a plurality of emissive regions corresponding to a plurality of color components, wherein
the plurality of emissive regions comprises:
a plurality of emissive elements each having an emissive element layer between two electrodes and which emit light of the same color, and
a plurality of color modifying elements provided on a side of the device closer to a side to be viewed than the emissive element to correspond to at least some of the plurality of emissive elements, for emitting light having an emission spectrum which is at least partially different from an emission spectrum of incident light;
light emission from the plurality of emissive elements is viewed, in the emissive regions corresponding to the plurality of color modifying elements, through the corresponding color modifying element and at least one layer which absorbs at least a portion of incident light; and
the areas of the plurality of emissive regions correspond to ratios of modification efficiencies corresponding to luminance of incident light and luminance of emitted light in the color modifying element and transmission efficiencies of the at least one layer absorbing at least a portion of the incident light, among different color components of the plurality of color components, and to a required luminance for each color component necessary for white display.

11. A color display device according to claim 10, wherein the areas of the plurality of emissive regions are directly proportional to a ratio, regarding each color component, between luminance of light emitted through the color modifying element and the at least one layer for absorbing at least a portion of the incident light and the luminance required for each color component necessary for white display.

12. A color display device according to claim 10, wherein the color modifying element filters incident light and allows transmission of light of a specific wavelength band.

13. A color display device according to claim 12, wherein the modification efficiency of the color modifying element corresponds to a transmission efficiency of the color modifying element.

14. A color display device according to claim 10, wherein the color modifying element changes the incident light into light of a different wavelength and emits the changed light.

15. A color display device according to claim 14, wherein the modification efficiency of the color modifying element corresponds to a color changing efficiency of a color changing material.

16. A color display device according to claim 10, wherein when a power is supplied with the same current density to the emissive elements provided in the plurality of emissive regions and light is emitted, a predetermined white display is achieved on a side to be viewed.

17. A color display device according to claim 10, wherein the at least one layer which absorbs at least a portion of the incident light includes an optical function layer.

18. A color display device according to claim 10, wherein the at least one layer which absorbs at least a portion of the incident light includes an insulating layer which is formed between the emissive element and a side of the device in which display is viewed.

19. A color display device having a first emissive region and a second emissive region associated with different color components, the color display device comprising:
a plurality of emissive elements each having an emissive element layer between two electrodes and which emit light of the same color, and
a first color modifying element and a second modifying element provided on a side of the device closer to a side to be viewed than the emissive element and corresponding to at least some of the plurality of emissive element, for emitting light of an emission spectrum which is at least partially different from an emission spectrum of the incident light, the first and second color modifying element emitting light of different colors, wherein
in the first emissive region, emission light from the emissive element is viewed through the first color modifying element;
in the second emissive region, emission light from the emissive element is viewed through the second color modifying element;
a modification efficiency corresponding to a ratio of light emitted from the first color modifying element with respect to light incident on the first color modifying element is higher than a modification efficiency corresponding to a ratio of light emitted from the second color modifying element with respect to light incident on the second color modifying element, and
an area of the first emissive region is smaller than an area of the second emissive region.

20. A color display device according to claim 19, wherein a ratio between the areas of the first emissive region and the second emissive region corresponds to a ratio between:
a luminance, required for white color display, of the color component corresponding to the first emissive region with respect to a luminance of the light emitted from the first color modifying element; and
a luminance, required for white color display, of the color component corresponding to the second emissive region with respect to a luminance of the light emitted from the second color modifying element.

21. A color display device having a first emissive region and a second emissive region associated with different color components, the color display device comprising:
a plurality of emissive elements each having an emissive element layer between two electrodes and which emit light of the same color, and
a first color modifying element and a second color modifying element provided on a side of the device closer to the side to be viewed than the emissive element and corresponding to at least some of the plurality of emissive elements, for emitting light of an emission spectrum which is at least partially different from an emission spectrum of the incident light, the first and second color modifying element emitting light of different colors, wherein
in the first emissive region, emission light from the emissive element is viewed through the first color modifying element;
in the second emissive region, emission light from the emissive element is viewed through the second color modifying element; and
when areas of the first and second emissive regions are S₁ and S₂, luminance of incident light to the first and second color modifying elements are L₁ and L₂, transmission efficiencies of the first and second color modifying elements are TE₁ and TE₂, and luminance of a first color component required in the first emissive region and luminance of a second color component required in the second emissive region for realizing a predetermined color by addition of colors are a₁ and a₂, the condition
S₁:S₂=a₁/(L₁·TE₁):a₂/(L₂·TE₂)
is satisfied.

22. A color display device having a first emissive region and a second emissive region associated with different color components, the color display device comprising:
a plurality of emissive elements each having an emissive element layer between two electrodes and which emit light of the same color; and
a first color modifying element and a second color modifying element provided on a side of the device closer to the side to be viewed than the emissive element and corresponding to at least some of the plurality of emissive elements for emitting light of an emission spectrum which is at least partially different from an emission spectrum of the incident light, the first and second color modifying elements emitting light of different colors, wherein
in the first emissive region, light emission from the emissive element is viewed through the first color modifying element;
in the second emissive region, light emission from the emissive element is viewed through the second color modifying element; and
when areas of the first and second emissive regions are S₁ and S₂, luminance of incident light to the first and second color modifying elements are L₁ and L₂, transmission efficiencies of the first and second color modifying elements are TE₁ and TE₂, luminance of the first color component required in the first emissive region and luminance of the second color component required in the second emissive region for realizing a predetermined color by addition of colors are a₁ and a₂, and luminance halflife of the first color component in the first emissive region and luminance halflife of the second color component in the second emissive regions when the emissive elements in the first and second emissive regions are driven by a current having the same current density are T₁ and T₂, the condition,
S₁:S₂=a₁/(L₁·TE₁·T₁):a₂/(L₂·TE₂·T₂)
is satisfied.

23. A color display device according to claim 22, wherein the luminance halflife of the first color component in the first emissive region and the luminance halflife of the second color component in the second emissive region are periods in which luminance of light of the first color component and light of the second color component are halved when the emissive elements of the first and second emissive regions are driven by currents having the same current density after an aging treatment is applied.

24. A color display device according to claim 23, wherein a rate of degradation of emission luminance is constant in at least one of the first and second color components.

25. A color display device comprising:
a plurality of emissive regions corresponding to a plurality of color components, wherein
the plurality of emissive regions comprises:
a plurality of emissive elements each having an emissive element layer between two electrodes and which emit light of the same color;
a plurality of color modifying elements provided at a side of the device closer to the side to be viewed than the emissive element and corresponding to at least some of the plurality of emissive elements, for emitting light having an emission spectrum which is at least partially different from an emission spectrum of incident light, wherein
in emissive regions to which the plurality of color modifying elements correspond, light emission from the plurality of emissive elements is viewed through the corresponding color modifying element; and
areas of the plurality of emissive regions correspond to ratios of modification efficiencies corresponding to luminance of incident light and luminance of emitted light in the color modifying element among different color components of the plurality of color components and to luminance required for each color component necessary for realizing a predetermined color represented by addition of colors.
